(19) United States
(12) Patent Application Publication
(10) Pub. No.: US 2025/0264642 A1
(43) Pub. Date: Aug. 21, 2025

(54) OUTPUT MIRROR FOR ULTRAVIOLET LASER BEAM, ULTRAVIOLET LASER APPARATUS, AND ELECTRONIC DEVICE MANUFACTURING METHOD

(71) Applicant: Gigaphoton Inc., Tochigi (JP)

(72) Inventor: Takahito KUMAZAKI, Oyama-shi (JP)

(73) Assignee: Gigaphoton Inc., Tochigi (JP)

(21) Appl. No.: 19/013,240

(22) Filed: Jan. 8, 2025

(30) Foreign Application Priority Data
Feb. 21, 2024 (JP) 2024-024647

(51) Int. Cl. G02B 5/08; H01S 3/08; H01S 3/10

(52) U.S. Cl. CPC G02B 5/0833; H01S 3/08059; H01S 3/10023

(57) ABSTRACT

An output mirror for an ultraviolet laser beam includes a plate-shaped sapphire substrate, at least a part of one main surface of the sapphire substrate is a partial reflective surface that is exposed, reflects a part of the ultraviolet laser beam, and transmits another part of the ultraviolet laser beam, and the other main surface of the sapphire substrate is provided with a reflection suppressing structure configured to suppress reflection of the ultraviolet laser beam.

### CROSS-REFERENCE TO RELATED APPLICATIONS

The present application claims the benefit of Japanese Patent Application No. 2024-24647, filed on Feb. 21, 2024, the entire contents of which are hereby incorporated by reference.

### BACKGROUND

### 1. Technical Field

The present disclosure relates to an output mirror for an ultraviolet laser beam, an ultraviolet laser apparatus, and an electronic device manufacturing method.

### 2. Related Art

In recent years, improvement in resolution has been desired for semiconductor exposure apparatuses with miniaturization and high integration of semiconductor integrated circuits. For this purpose, exposure light sources that output light having shorter wavelengths have been developed. For example, as gas laser apparatuses for exposure, a KrF excimer laser apparatus that outputs a laser beam having a wavelength of about 248.0 nm and an ArF excimer laser apparatus that outputs a laser beam having a wavelength of about 193.4 nm are used.

Spectral line widths of self-oscillation light of the KrF excimer laser apparatus and the ArF excimer laser apparatus are as wide as 350 μm to 400 μm. Therefore, when a projection lens is configured of a material that transmits ultraviolet light such as a KrF laser beam and an ArF laser beam, chromatic aberration may occur. As a result, the resolution may decrease. Thus, a spectral line width of a laser beam output from a gas laser apparatus needs to be narrowed to the extent that the chromatic aberration can be ignored. Therefore, a line narrowing module (LNM) including a line narrowing element (etalon, grating, or the like) may be included inside a laser resonator of the gas laser apparatus in order to narrow the spectral line width. In the following, a gas laser apparatus with a narrowed spectral line width will be referred to as a line narrowed gas laser apparatus.

### LIST OF DOCUMENTS

### Patent Documents

Patent Document 1: U.S. Pat. No. 6,642,989
Patent Document 2: U.S. Pat. No. 5,507,175
Patent Document 3: U.S. Pat. No. 7,756,189
Patent Document 4: U.S. Pat. No. 11,784,452

### SUMMARY

An aspect of the present disclosure is an output mirror for an ultraviolet laser beam including a plate-shaped sapphire substrate, at least a part of one main surface of the sapphire substrate may be a partial reflective surface that is exposed, reflects a part of the ultraviolet laser beam, and transmits another part of the ultraviolet laser beam, and the other main surface of the sapphire substrate may be provided with a reflection suppressing structure configured to suppress reflection of the ultraviolet laser beam.

Moreover, another aspect of the present disclosure is an ultraviolet laser apparatus including an amplifier configured to amplify an ultraviolet laser beam, the amplifier may include an output mirror for the ultraviolet laser beam, the output mirror may include a plate-shaped sapphire substrate, at least a part of one main surface of the output mirror may be a partial reflective surface from which the sapphire substrate is exposed, the partial reflective surface reflecting a part of the ultraviolet laser beam and transmitting another part of the ultraviolet laser beam, and the other main surface of the output mirror may be provided with a reflection suppressing structure configured to suppress reflection of the ultraviolet laser beam.

Furthermore, yet another aspect of the present disclosure is an electronic device manufacturing method that may include: generating an ultraviolet laser beam with an ultraviolet laser apparatus including an output mirror for the ultraviolet laser beam, the output mirror including a plate-shaped sapphire substrate, at least a part of one main surface of the output mirror being a partial reflective surface from which the sapphire substrate is exposed, the partial reflective surface reflecting a part of the ultraviolet laser beam and transmitting another part of the ultraviolet laser beam, the other main surface of the output mirror being provided with a reflection suppressing structure configured to suppress reflection of the ultraviolet laser beam; outputting the ultraviolet laser beam to an exposure apparatus; and exposing a photosensitive substrate to the ultraviolet laser beam within the exposure apparatus to manufacture an electronic device.

### BRIEF DESCRIPTION OF THE DRAWINGS

Some embodiments of the present disclosure will be described below merely as examples with reference to the accompanying drawings.

FIG. 1 is a schematic diagram illustrating an overall schematic configuration example of an electronic device manufacturing apparatus.

FIG. 2 is a schematic diagram illustrating an overall schematic configuration example of an ultraviolet laser apparatus of a comparative example.

FIG. 3 is a schematic diagram illustrating a schematic configuration example of an output mirror included in the ultraviolet laser apparatus of the comparative example.

FIG. 4 is a schematic diagram illustrating a schematic configuration example of an output mirror of the first embodiment.

FIG. 5 is a graph illustrating a relationship between a substrate refractive index and a surface reflectance due to Fresnel reflection.

FIG. 6 is a schematic diagram illustrating disposition of an output mirror in a first modification of the first embodiment.

FIG. 7 is a schematic diagram illustrating disposition of an output mirror in a second modification of the first embodiment.

FIG. 8 is a schematic diagram illustrating disposition of an output mirror in a third modification of the first embodiment.

FIG. 9 is a schematic diagram illustrating a positional relationship between an output mirror and a window of a chamber device in a fourth modification of the first embodiment.

FIG. 10 is a schematic diagram of a case where a moth eye structure is included as a reflection suppressing structure of an output mirror in an ultraviolet laser apparatus according to a second embodiment.

FIG. 11 is an explanatory diagram of the moth eye structure.

FIG. 12 is a schematic diagram illustrating a schematic configuration example of a part of an amplifier included in an ultraviolet laser apparatus of a third embodiment.

FIG. 13 is a graph illustrating incident angle dependence of a reflectance of Fresnel reflection.

### DESCRIPTION OF EMBODIMENTS

1. Description of electronic device manufacturing apparatus used in electronic device exposure process
2. Description of ultraviolet laser apparatus of comparative example
   2.1 Configuration
   2.2 Operation
   2.3 Problem
3. Description of ultraviolet laser apparatus of first embodiment
   3.1 Configuration
   3.2 Operation
   3.3 Effect and advantage
   3.4 Description of first modification
   3.5 Description of second modification
   3.6 Description of third modification
   3.7 Description of fourth modification
4. Description of ultraviolet laser apparatus of second embodiment
   4.1 Configuration
   4.2 Effect and advantage
5. Description of ultraviolet laser apparatus of third embodiment
   5.1 Configuration
   5.2 Operation
   5.3 Effect and advantage

Hereinafter, embodiments of the present disclosure will be described in detail with reference to the drawings. The embodiments described below illustrate some examples of the present disclosure and do not limit the content of the present disclosure. Also, all configurations and operations described in the embodiments are not necessarily essential as configurations and operations of the present disclosure. Note that the same components will be denoted by the same reference signs, and repeated description will be omitted.

### 1. Description of Electronic Device Manufacturing Apparatus Used in Electronic Device Exposure Process

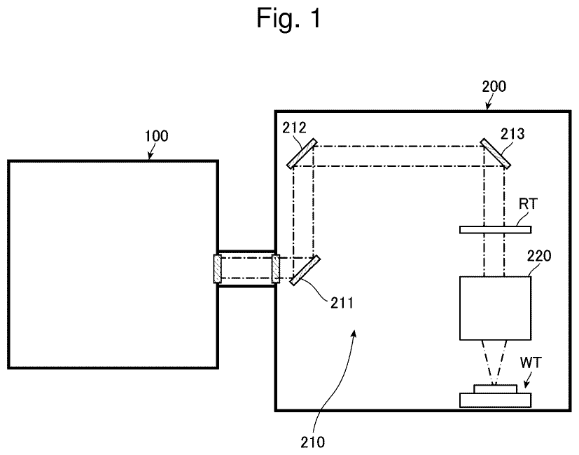

FIG. 1 is a schematic diagram illustrating an overall schematic configuration example of an electronic device manufacturing apparatus used in an electronic device exposure process. As illustrated in FIG. 1, the manufacturing apparatus used in the exposure process includes an ultraviolet laser apparatus 100 and an exposure apparatus 200. The exposure apparatus 200 includes an illumination optical system 210 including a plurality of mirrors 211, 212, and 213 and a projection optical system 220. The illumination optical system 210 illuminates a reticle pattern on a reticle stage RT with a laser beam that is incident from the ultraviolet laser apparatus 100. The projection optical system 220 performs reduction projection of the laser beam transmitted through the reticle and forms an image on an unillustrated workpiece disposed on a workpiece table WT. The workpiece is a photosensitive substrate such as a semiconductor wafer to which a photoresist is applied. The exposure apparatus 200 synchronously translates the reticle stage RT and the workpiece table WT to expose the workpiece to a laser beam reflecting the reticle pattern. A device pattern is transferred onto the semiconductor wafer through the exposure process as described above to thereby manufacture a semiconductor device, which is an electronic device.

### 2. Description of Ultraviolet Laser Apparatus of Comparative Example

### 2.1 Configuration

An ultraviolet laser apparatus of a comparative example will be described. Note that the comparative example of the present disclosure is an example recognized by the applicant as known only by the applicant, and is not a publicly known example admitted by the applicant.

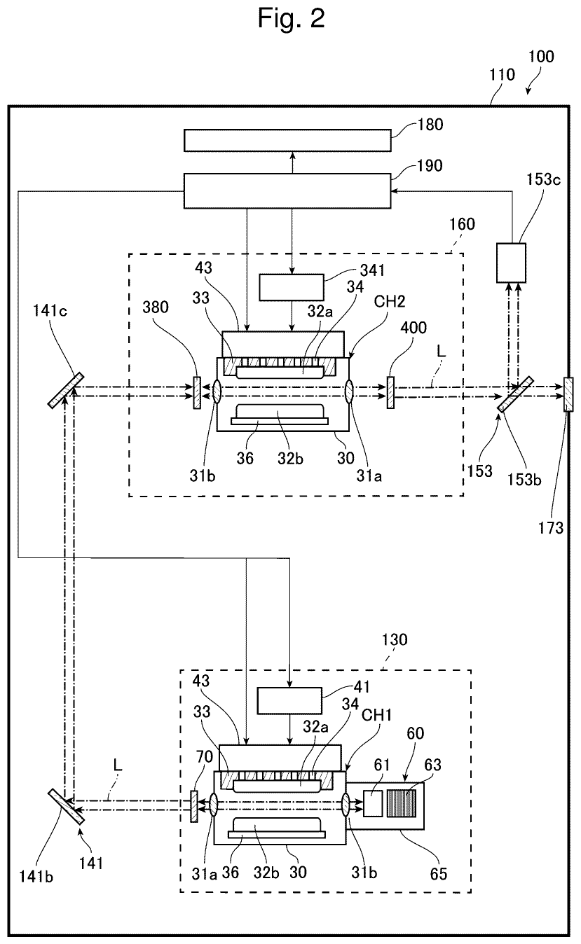

FIG. 2 is a schematic diagram illustrating an overall configuration example of an ultraviolet laser apparatus 100 of the present example. The ultraviolet laser apparatus 100 is, for example, an ArF excimer laser apparatus using mixed gas including argon (Ar), fluorine (F₂), and neon (Ne). The ultraviolet laser apparatus 100 outputs a laser beam L having a center wavelength of about 193.4 nm. Note that in the specification, the term “laser beam” means an ultraviolet laser beam. The ultraviolet laser apparatus 100 may be a gas laser apparatus other than the ArF excimer laser apparatus, and may be, for example, a KrF excimer laser apparatus using KrF gas including krypton (Kr) and fluorine (F₂). In this case, the ultraviolet laser apparatus 100 emits a pulsed laser beam having a center wavelength of about 248 nm. ArF gas or KrF gas, which is a laser medium, may be referred to as laser gas. Therefore, the ultraviolet laser beam may be an ArF laser beam having a center wavelength of about 193.4 nm or a KrF laser beam having a center wavelength of 248 nm.

The ultraviolet laser apparatus 100 of the present example includes, as main components, a housing 110, a laser oscillator 130 that is a master oscillator disposed in an internal space of the housing 110, a light transmission unit 141, an amplifier 160 that is a power oscillator, a detection unit 153, a display unit 180, and a processor 190.

The laser oscillator 130 includes, as main components, a chamber device CH1, a charger 41, a pulse power module 43, a line narrowing module 60, and an output mirror 70.

FIG. 2 illustrates an internal configuration of the chamber device CH1 seen from a direction substantially perpendicular to a traveling direction of the laser beam L. The chamber device CH1 includes, as main components, a housing 30, a pair of windows 31a and 31b, a pair of electrodes 32a and 32b, an insulating unit 33, a feedthrough 34, and an electrode holder unit 36.

The housing 30 encloses the laser gas in the internal space. The internal space is a space in which light is generated by excitation of the laser medium in the laser gas. This light travels to the windows 31a and 31b.

The window 31a is disposed on a front-side wall surface of the housing 30 in the traveling direction of the laser beam L from the ultraviolet laser apparatus 100 to the exposure apparatus 200, and the window 31b is disposed on a rear-side wall surface of the housing 30 in the traveling direction. The windows 31a and 31b are made of, for example, calcium fluoride substrates, and the inner and outer surfaces of the housing 30 at the windows 31a and 31b are planar. Note that it is only necessary for the windows 31a and 31b to be able to transmit the laser beam L and the windows 31a and 31b are not limited to the calcium fluoride substrates.

The electrodes 32a and 32b are disposed to face each other in the internal space of the housing 30, and a longitudinal direction of the electrodes 32a and 32b follows a traveling direction of light generated by a high voltage applied between the electrode 32a and the electrode 32b. A discharge space between the electrode 32a and the electrode 32b in the housing 30 is sandwiched between the window 31a and the window 31b. The electrodes 32a and 32b are discharge electrodes for exciting the laser medium by glow discharge. In the present example, the electrode 32a is a cathode, and the electrode 32b is an anode.

The electrode 32a is supported by the insulating unit 33. The insulating unit 33 blocks an opening formed in the housing 30. The insulating unit 33 includes an insulator. In addition, the feedthrough 34 made of a conductive member is disposed in the insulating unit 33. The feedthrough 34 applies a voltage supplied from the pulse power module 43 to the electrode 32a. The electrode 32b is supported by the electrode holder unit 36 and is electrically connected to the electrode holder unit 36 having a ground potential.

The charger 41 is a DC power supply device that charges an unillustrated capacitor, which is provided inside the pulse power module 43, with a predetermined voltage. The charger 41 is disposed outside the housing 30 and is connected to the pulse power module 43. The pulse power module 43 includes an unillustrated switch controlled by the processor 190. The pulse power module 43 is a voltage application circuit that, when a switch is turned from OFF to ON by the control, boosts the voltage applied from the charger 41 to generate a pulsed high voltage and applies the high voltage to the electrodes 32a and 32b. When the high voltage is applied, discharge occurs between the electrode 32a and the electrode 32b. The laser medium inside the housing 30 is excited by energy of the discharge. When the excited laser gas transitions to a ground level, light is emitted, and the emitted light passes through the windows 31a and 31b and is output to the outside of the housing 30. The windows 31a and 31b are inclined to form a Brewster angle with respect to the traveling direction of the laser beam L such that reflection of P-polarized light of the laser beam L is suppressed, and in the present example, the windows 31a and 31b are inclined with respect to a direction perpendicular to the traveling direction of the laser beam L and the direction in which the electrodes 32a and 32b face each other. Therefore, the laser beam L exiting the chamber device CH1 includes first linearly polarized light, a polarization direction of which is perpendicular to the direction in which the electrodes 32a and 32b face each other, and linearly polarized light, a polarization direction of which differs from the polarization direction of the first linearly polarized light, is reduced from the laser beam L. In other words, the windows 31a and 31b also serve as polarizers that are inclined with respect to the polarization direction of the first linearly polarized light and reduces the linearly polarized light in the polarization direction that differs from the polarization direction of the first linearly polarized light from the laser beam L.

Note that in the specification and claims, the term “perpendicular” refers to a state in which the angle formed is equal to or greater than 89 degrees and equal to or less than 91 degrees, and the term “parallel” refers to a state in which the angle formed is within 1 degree.

The line narrowing module 60 includes a housing 65, a prism 61 disposed in an internal space of the housing 65, a grating 63, and an unillustrated rotation stage. An opening is formed in the housing 65, and the housing 65 is connected to a rear side of the housing 30 via the opening.

The prism 61 expands a beam width of light exiting the window 31b and causes the light to be incident on the grating 63. Furthermore, the prism 61 reduces a beam width of reflected light from the grating 63 and returns the light to the internal space of the housing 30 via the window 31b. The prism 61 is supported by the rotation stage and is rotated by the rotation stage. The rotation of the prism 61 can change an incident angle of the light with respect to the grating 63, and a wavelength of the light returning from the grating 63 to the housing 30 via the prism 61 can be selected. Although FIG. 2 illustrates an example in which one prism 61 is disposed, two or more prisms may be disposed.

A surface of the grating 63 is made of a material having a high reflectance, and a large number of grooves are provided at predetermined intervals in the surface. The grating 63 is a dispersive optical element. The cross-sectional shape of each groove is, for example, a right-angled triangle. Light that is incident on the grating 63 from the prism 61 is reflected by these grooves and is diffracted in a direction in accordance with a wavelength of the light. The grating 63 is disposed in Littrow arrangement such that the incident angle of the light that is incident on the grating 63 from the prism 61 coincides with a diffraction angle of the diffracted light having a desired wavelength. Thus, light having a desired wavelength is returned to the housing 30 via the prism 61.

The output mirror 70 faces the window 31a, transmits a part of the laser beam L exiting the window 31a, reflects and returns the other part of the laser beam L to the internal space of the housing 30 via the window 31a. The output mirror 70 is fixed to an unillustrated holder and is disposed in an internal space of the housing 110.

A Fabry-Perot-type resonator is formed by the grating 63 and the output mirror 70 between which the housing 30 is sandwiched, and the housing 30 is disposed on an optical path of the resonator. Therefore, the resonator resonates light between the output mirror 70 and the grating 63 sandwiching the chamber device CH1.

The light transmission unit 141 includes, as main components, high reflective mirrors 141b and 141c. Each of the high reflective mirrors 141b and 141c is fixed to an unillustrated holder with the inclination angle thereof adjusted, and is disposed in the internal space of the housing 110. The high reflective mirrors 141b and 141c highly reflect the laser beam L. The high reflective mirrors 141b and 141c are disposed on the optical path of the laser beam L from the output mirror 70. The laser beam L is reflected by the high reflective mirrors 141b and 141c and is then incident on the amplifier 160.

The amplifier 160 amplifies energy of the laser beam L output from the laser oscillator 130. A basic configuration of the amplifier 160 includes, as main components, a chamber device CH2, a charger 341, a rear mirror 380, and an output mirror 400, which are components substantially similar to those of the laser oscillator 130. Note that the same components as those of the laser oscillator 130 will be denoted by the same reference signs, and detailed description thereof will be omitted unless otherwise specified.

The electrodes 32a and 32b generate discharge for amplifying the laser beam L from the laser oscillator 130. The direction in which the electrodes 32a and 32b face each other is a direction perpendicular to the polarization direction of the first linearly polarized light in the laser beam L from the laser oscillator 130. The windows 31a and 31b are inclined with respect to the polarization direction of the first linearly polarized light such that the first linearly polarized light in the laser beam L is incident as P-polarized light and an incident angle θ of the laser beam L becomes the Brewster angle. Therefore, the laser beam L exiting the chamber device CH2 includes the first linearly polarized light, and linearly polarized light in a polarization direction that differs from the polarization direction of the first linearly polarized light is reduced from the laser beam L.

Note that the amplifier 160 is different from the laser oscillator 130 in that the amplifier 160 does not include the line narrowing module 60 and includes the rear mirror 380.

The rear mirror 380 is provided between the high reflective mirror 141c and the window 31b and face each of the high reflective mirror 141c and the window 31b. The rear mirror 380 transmits the laser beam L from the laser oscillator 130 toward a discharge space between the electrodes 32a and 32b, and reflects a part of the laser beam L amplified by the electrode 32a and 32b and exiting the chamber device CH2 toward the discharge space between the electrodes 32a and 32b.

The output mirror 400 is disposed on a side opposite to the side of the rear mirror 380 relative to the chamber device CH2. The output mirror 400 reflects a part of the laser beam L from the chamber device CH2 and transmits the other part of the laser beam L. A surface of the output mirror 400 on the side of the chamber device CH2 is coated with a partial reflective film having a predetermined reflectance. Furthermore, a surface of the output mirror 400 on the side opposite to the chamber device CH 2 is coated with a non-reflective film having a reflectance of approximately zero.

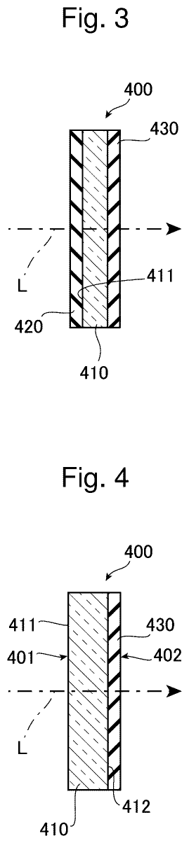

FIG. 3 is a schematic diagram illustrating a schematic configuration example of the output mirror 400 included in the ultraviolet laser apparatus 100 of the comparative example. The output mirror 400 may be disc-shaped. The surface of the output mirror 400 on the side of the chamber device CH2 and the surface on the opposite side may be flat. The output mirror 400 includes a plate-shaped substrate 410. One main surface 411 of the substrate 410 is provided with a partial reflective film 420 having a reflectance of 10% to 20%, and the other main surface is provided with a reflection suppressing film 430 having a reflectance of approximately 0%. The substrate 410 is made of, for example, CaF₂, MgF₂, or synthetic quartz. The partial reflective film 420 and the reflection suppressing film 430 have structures formed of dielectric multilayer films in which high refractive index material layers and low refractive index material layers are alternately laminated. By adjusting the thicknesses of the high refractive index material layers and the low refractive index material layers, desired reflectance of the partial reflective film 420 and the reflection suppressing film 430 is attained. Examples of the material of the high refractive index material layer include dielectric materials such as LaF₃ and GdF₃, and examples of the material of the low refractive index material layer include a dielectric material such as MgF₂.

The detection unit 153 includes, as main components, a beam splitter 153b and an optical sensor 153c.

The beam splitter 153b is disposed on the optical path of the laser beam L transmitted through the output mirror 400. The beam splitter 153b transmits the laser beam L transmitted through the output mirror 400 toward an exit window 173 with a higher transmittance, and reflects a part of the laser beam L toward a light receiving surface of the optical sensor 153c.

The optical sensor 153c measures pulsed energy of the laser beam L that is incident on the light receiving surface of the optical sensor 153c. The optical sensor 153c is electrically connected to the processor 190 and outputs a signal indicative of the measured pulsed energy to the processor 190. The processor 190 controls a voltage to be applied to the electrodes 32a and 32b of the laser oscillator 130 and/or the amplifier 160 on the basis of the signal.

The exit window 173 is provided on a side opposite to the output mirror 400 with reference to the beam splitter 153b of the detection unit 153. The exit window 173 is provided on a wall of the housing 110. Light transmitted through the beam splitter 153b exits the emission window 173 toward the exposure apparatus 200 outside the housing 110. The laser beam L is, for example, a pulsed laser beam having a center wavelength of 193.4 nm.

The display unit 180 is a monitor that displays a state of control performed by the processor 190 on the basis of a signal from the processor 190. The display unit 180 may be disposed outside the housing 110.

The processor 190 of the present disclosure is a processing device including a storage device that stores a control program and a central processing unit (CPU) that executes the control program. The processor 190 is specifically configured or programmed to perform various kinds of processing included in the present disclosure. The processor 190 controls the entire ultraviolet laser apparatus 100. The processor 190 is electrically connected to an unillustrated exposure processor of the exposure apparatus 200, and transmits and receives various signals to and from the exposure processor.

### 2.2 Operation

Next, an operation of the ultraviolet laser apparatus 100 of the comparative example will be described.

When the ultraviolet laser apparatus 100 emits the laser beam L, the processor 190 receives a signal indicating target energy Et and a light emission trigger signal from the unillustrated exposure processor of the exposure apparatus 200. The target energy Et is a target value of energy of the laser beam L used in the exposure process. The processor 190 sets a predetermined charge voltage in the charger 341 such that energy E becomes the target energy Et, and turns ON the switch of the pulse power module 43 in synchronization with the light emission trigger signal. In this manner, the pulse power module 43 generates a pulsed high voltage from electric energy held in the charger 41, and the high voltage is applied between the electrode 32a and the electrode 32b. When the high voltage is applied, discharge occurs between the electrode 32a and the electrode 32b, and the laser medium contained in the laser gas between the electrode 32a and the electrode 32b is brought into an excited state and emits light when the laser medium returns to the ground state. The emitted light resonates between the grating 63 and the output mirror 70 and is amplified every time the light passes through the discharge space in the internal space of the housing 30, and laser oscillation occurs. The laser beam L includes first linearly polarized light, and linearly polarized light in a polarization direction that differs from the polarization direction of the first linearly polarized light is reduced from the laser beam L when the laser beam L is transmitted through the windows 31a and 31b. A part of the laser beam L is transmitted through the output mirror 70, is reflected by the high reflective mirrors 141b and 141c, and travels into the amplifier 160. In the amplifier 160, the laser beam L is transmitted through the rear mirror 380 and the window 31b and travels into the housing 30 of the chamber device CH2.

The processor 190 turns ON the switch of the pulse power module 43 of the amplifier 160 such that discharge occurs when the laser beam L from the laser oscillator 130 travels into the discharge space in the housing 30 of the amplifier 160. In other words, the processor 190 controls the pulse power module 43 such that a high voltage is applied to the electrodes 32a and 32b of the amplifier 160 after elapse of a predetermined delay time with respect to the timing at which the switch of the pulse power module 43 is turned ON.

In this manner, the laser beam L that is incident on the amplifier 160 is amplified by the amplifier 160. In addition, the laser beam L traveling into the internal space of the housing 30 travels to the output mirror 400 via the window 31a as described above, and a part of the laser beam L is reflected by the partial reflective film 420 of the output mirror 400. The laser beam L reflected by the output mirror 400 travels into the internal space of the housing 30 via the window 31a, is amplified, and exits the window 31b. The light exiting the window 31b is reflected by the rear mirror 380 and travels into internal space of the housing 30 via the window 31b. In this manner, the laser beam L having a predetermined wavelength reciprocates between the rear mirror 380 and the output mirror 400. The laser beam L includes the first linearly polarized light, and the linearly polarized light in the polarization direction that differs from the polarization direction of the first linearly polarized light is reduced from the laser beam L when the laser beam L is transmitted through the windows 31a and 31b. Furthermore, the laser beam L is amplified every time the laser beam L passes through the discharge space inside the housing 30.

The other part of the laser beam L amplified by the chamber device CH2 and exiting the window 31a is transmitted through the output mirror 400 and travels to the beam splitter 153b.

A part of the laser beam L traveling to the beam splitter 153b is transmitted through the beam splitter 153b and travels to the exit window 173, and the other part is reflected by the beam splitter 153b and travels to the optical sensor 153c.

The optical sensor 153c measures the energy E of the received laser beam L. The optical sensor 153c outputs a signal indicating the measured energy E to the processor 190. The processor 190 feedback-controls a charge voltage of the charger 341 such that a difference ΔE between the energy E and the target energy Et falls within an allowable range. At this time, the processor 190 may close an unillustrated shutter disposed in front of the exit window 173 until the difference ΔE falls within the allowable range such that the laser beam L is not incident on the exposure apparatus 200.

### 2.3 Problem

With an increase in throughput of the exposure apparatus 200, there is an increasing demand for an increase in output of the ultraviolet laser apparatus 100 which is a light source. The ultraviolet laser beam L transmitted through the output mirror 400 of the amplifier 160 is light after amplification and thus has a high energy density. Therefore, when the output of the light source is increased, deterioration of the dielectric multilayer film constituting the partial reflective film 420 may be accelerated. Therefore, there is a demand for a more durable output mirror that can withstand the demand for an increase in output.

In the following embodiments, a highly durable output mirror and a highly durable ultraviolet laser apparatus will be exemplified.

### 3. Description of Ultraviolet Laser Apparatus of First Embodiment

An output mirror 400 and an ultraviolet laser apparatus 100 of the present embodiment will be described. Note that the same components as those described above will be denoted by the same reference signs, and repeated description thereof will be omitted unless particularly explained.

### 3.1 Configuration

The ultraviolet laser apparatus 100 of the present embodiment is different from the ultraviolet laser apparatus 100 of the comparative example only in the configuration of the output mirror 400. Therefore, description of the entire configuration of the ultraviolet laser apparatus 100 will be omitted.

FIG. 4 is a schematic diagram illustrating the output mirror 400 according to the present embodiment. In the present embodiment, a substrate 410 of the output mirror 400 is a sapphire substrate made of a sapphire crystal. Hereinafter, the substrate 410 will be described as a sapphire substrate 410. At least a part of one main surface 411 of the sapphire substrate 410 is exposed. In other words, at least a part of the one main surface 411 is a non-coated surface on which a layer or the like made of a material different from that of the sapphire substrate 410 is not provided. The one main surface 411 is a partial reflective surface 401 that reflects a part of an ultraviolet laser beam L and transmits the other part of the ultraviolet laser beam L. Note that although an example in which the entire one main surface 411 is exposed is illustrated in the example of FIG. 4, it is only necessary for a part of the one main surface 411 that is the partial reflective surface 401 to be exposed and the other part of the one main surface 411 may be coated.

An ultraviolet light transmittance of the sapphire crystals constituting the sapphire substrate 410 may not be sufficiently high as compared with CaF₂ which is one of materials of the substrate 410 used in the output mirror 400 of the comparative example in the current situation. Therefore, although the thickness of the sapphire substrate 410 is preferably as thin as possible, it is also necessary to maintain strength and surface precision. From these viewpoints, the thickness of the sapphire substrate 410 is preferably equal to or greater than 1 mm and equal to or less than 7 mm, and is more preferably equal to or greater than 1 mm and equal to or less than 5 mm.

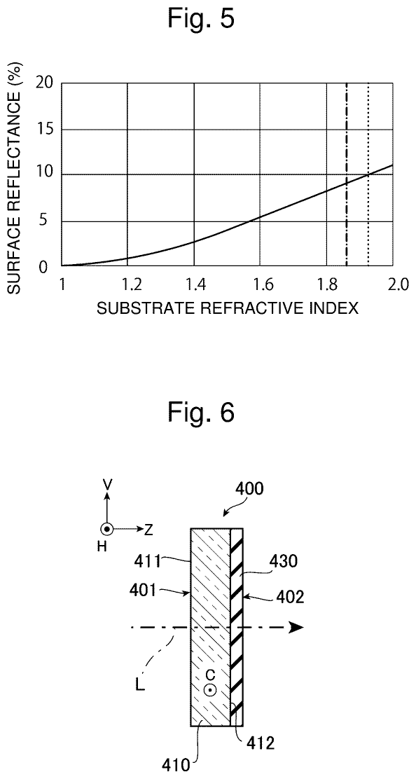

FIG. 5 is a graph illustrating a relationship between a substrate refractive index and a surface reflectance due to Fresnel reflection. The sapphire crystals have an ordinary refractive index of 1.929 and an extraordinary refractive index of 1.917 for ultraviolet light having a wavelength of 193 nm. As illustrated by a dotted line in FIG. 5, it can be seen that the reflectance of Fresnel reflection on the one main surface 411 of the sapphire substrate 410 is approximately 10% for the ultraviolet light having a wavelength of 193 nm. Therefore, the reflectance of the partial reflective surface 401 in the configuration in which the one main surface 411 of the sapphire substrate 410 is exposed is approximately 10% for the ultraviolet light having a wavelength of 193 nm. Therefore, when the ultraviolet laser apparatus 100 is an ArF excimer laser apparatus, the reflectance of the partial reflective surface 401 of the output mirror 400 is approximately 10%.

In addition, the ordinary refractive index of the sapphire crystals for ultraviolet light having a wavelength of 248 nm is 1.8467. As illustrated by the one-dotted dashed line in FIG. 5, the reflectance of Fresnel reflectance on the one main surface 411 of the sapphire substrate 410 for the ultraviolet light having a wavelength of 248 nm is approximately 98. Therefore, the reflectance of the partial reflective surface 401 in the configuration in which the one main surface 411 of the sapphire substrate 410 is exposed is approximately 9% for the ultraviolet light having a wavelength of 248 nm. Therefore, when the ultraviolet laser apparatus 100 is a KrF excimer laser apparatus, the reflectance of the partial reflective surface 401 of the output mirror 400 is approximately 9%.

A reflection suppressing structure 402 that suppresses reflection of the ultraviolet laser beam L is provided on the other main surface 412 of the sapphire substrate 410 opposing the one main surface 411. In the present embodiment, the reflection suppressing structure 402 has a configuration that is similar to that of the reflection suppressing film 430 of the comparative example, and has a structure including a dielectric multilayer film.

The output mirror 400 is disposed such that the partial reflective surface 401 faces a side of a chamber device CH2 and the reflection suppressing structure 402 faces a side of an exit window 173 such that the partial reflective surface 401 is perpendicular to the ultraviolet laser beam L exiting the chamber device CH2.

### 3.2 Operation

As described above, since the reflectance of the partial reflective surface 401, which is the exposed one main surface 411 of the sapphire substrate 410, is approximately 10% for the ultraviolet light having a wavelength of 193 nm, a part of the ultraviolet laser beam L that is incident on the output mirror 400 is reflected by the partial reflective surface 401 and the other part thereof is transmitted therethrough when the ultraviolet laser beam L exits the ultraviolet laser apparatus 100. Then, an amplifier 160 amplifies and outputs the ultraviolet laser beam L similarly to the ultraviolet laser apparatus 100 of the comparative example.

### 3.3 Effect and Advantage

The output mirror 400 of the present embodiment includes the plate-shaped sapphire substrate 410, and at least a part of the one main surface 411 of the sapphire substrate 410 is the partial reflective surface 401 that is exposed, reflects a part of the ultraviolet laser beam L, and transmits the other part of the ultraviolet laser beam L, and the other main surface 412 of the sapphire substrate 410 is provided with the reflection suppressing structure 402 that suppresses reflection of the ultraviolet laser beam L. In this manner, since the multilayer film is not formed on the partial reflective surface 401 in the output mirror 400 of the present embodiment, no deterioration of the multilayer film occurs, and high durability can be achieved with respect to the high-output ultraviolet laser beam L with a high energy density. In addition, the ultraviolet laser apparatus 100 including the output mirror 400 of the present embodiment can have high durability.

### 3.4 Description of First Modification

A first modification of the ultraviolet laser apparatus 100 of the first embodiment will be described. Note that the same components as those described above will be denoted by the same reference signs, and repeated description thereof will be omitted unless specifically explained.

As described above, since the output mirror 400 includes the sapphire substrate 410 and the sapphire crystal that is the material of the substrate 410 is a birefringent material, influences of birefringence can be reduced by appropriately selecting a crystal orientation and a direction of polarization of incident light.

FIG. 6 is a schematic diagram illustrating disposition of the output mirror 400 in the present modification. As illustrated in FIG. 6, the c axis of the sapphire crystal that is the material of the sapphire substrate 410 is oriented in a direction perpendicular to the plane of the paper in this modification. Therefore, the c axis of the sapphire crystal that is the material of the sapphire substrate 410 is parallel to the partial reflective surface 401 that is the one main surface. Furthermore, in the present modification, the polarization direction of the ultraviolet laser beam L exiting the chamber device CH2 of the amplifier 160 is oriented in an H direction. In other words, the output mirror 400 is disposed such that the polarization direction of the ultraviolet laser beam L that is incident on the output mirror 400 is parallel to the c axis of the sapphire crystal that is the material of the sapphire substrate 410. Note that the optical axis of the ultraviolet laser beam L and the partial reflective surface 401 of the output mirror 400 are perpendicular to each other. This disposition of the output mirror 400 can reduce the influences of birefringence due to the sapphire substrate 410.

### 3.5 Description of Second Modification

A second modification of the ultraviolet laser apparatus 100 of the first embodiment will be described. Note that the same components as those described above will be denoted by the same reference signs, and repeated description thereof will be omitted unless specifically explained.

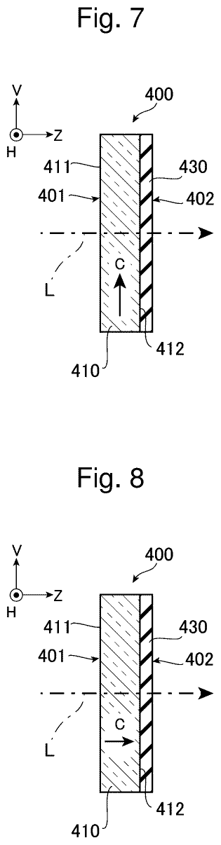

FIG. 7 is a schematic diagram illustrating disposition of the output mirror 400 in the present modification. As illustrated in FIG. 7, the c axis of the sapphire crystal that is the material of the sapphire substrate 410 is oriented in a direction parallel to a V direction in the present modification. Therefore, the c axis of the sapphire crystal that is the material of the sapphire substrate 410 is parallel to the partial reflective surface 401 that is the one main surface. In addition, the polarization direction of the ultraviolet laser beam L exiting the chamber device CH2 of the amplifier 160 in the present modification is also similar to that in the first modification. In other words, the output mirror 400 is disposed such that the polarization direction of the ultraviolet laser beam L that is incident on the output mirror 400 is perpendicular to the c axis of the sapphire crystal that is the material of the sapphire substrate 410. Note that the optical axis of the ultraviolet laser beam L and the partial reflective surface 401 of the output mirror 400 are perpendicular to each other. This disposition of the output mirror 400 can reduce the influences of birefringence due to the sapphire substrate 410.

### 3.6 Description of Third Modification

A third modification of the ultraviolet laser apparatus 100 of the first embodiment will be described. Note that the same components as those described above will be denoted by the same reference signs, and repeated description thereof will be omitted unless specifically explained.

FIG. 8 is a schematic diagram illustrating disposition of the output mirror 400 in the present modification. As illustrated in FIG. 8, the c axis of the sapphire crystal that is the material of the sapphire substrate 410 is oriented in a direction parallel to a Z direction in the present modification. In other words, the output mirror 400 is disposed such that the optical axis of the ultraviolet laser beam L that is incident on the output mirror 400 is parallel to the c axis of the sapphire crystal that is the material of the sapphire substrate 410. Therefore, the c axis of the sapphire crystal that is the material of the sapphire substrate 410 is perpendicular to the partial reflective surface 401 that is the one main surface. Note that the optical axis of the ultraviolet laser beam L and the partial reflective surface 401 of the output mirror 400 are perpendicular to each other. This disposition of the output mirror 400 can reduce the influences of birefringence due to the sapphire substrate 410.

### 3.7 Description of Fourth Modification

A fourth modification of the ultraviolet laser apparatus 100 of the first embodiment will be described. Note that the same components as those described above will be denoted by the same reference signs, and repeated description thereof will be omitted unless specifically explained.

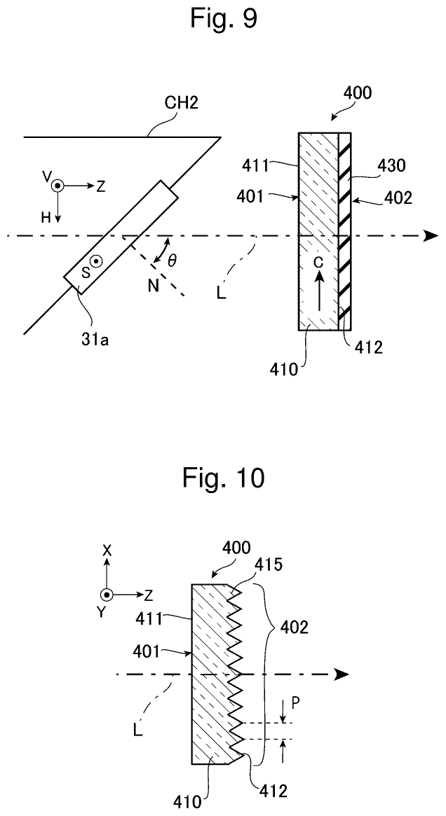

FIG. 9 is a schematic diagram illustrating a positional relationship between the output mirror 400 and the window 31a of the chamber device CH2 in the present modification. In the present modification, the window 31a that is provided in the chamber device CH2 and from which the ultraviolet laser beam L exits is disposed to be inclined such that an angle θ formed between a normal line N of a main surface of the window 31a and the optical axis of the ultraviolet laser beam L forms a Brewster angle. An inclination axis S of the window 31a is a rotational axis when the main surface of the window 31a is inclined to form the Brewster angle as described above from a state perpendicular to the optical axis of the ultraviolet laser beam L, and is parallel to the V axis as illustrated in FIG. 9. Therefore, the inclination axis S is perpendicular to the optical axis of the ultraviolet laser beam L that is incident on the output mirror 400. Furthermore, as illustrated in FIG. 9, the c axis of the sapphire crystal that is the material of the sapphire substrate 410 is oriented in a direction parallel to the H direction in this modification. In other words, in the present modification, the output mirror 400 is arranged such that the c axis of the sapphire crystal that is the material of the sapphire substrate 410 is perpendicular to the inclination axis S of the window 31a provided in the chamber device CH2 and a propagation direction of the ultraviolet laser beam L. This disposition of the output mirror 400 can reduce window reflected light of the ultraviolet laser beam L exiting the chamber device CH2 and the influences of birefringence due to the sapphire substrate 410.

### 4. Description of Ultraviolet Laser Apparatus of Second Embodiment

Next, an output mirror 400 of a second embodiment will be described. Note that the same components as those described above will be denoted by the same reference signs, and repeated description thereof will be omitted unless specifically explained.

### 4.1 Configuration

FIG. 10 is a schematic diagram illustrating the output mirror 400 in the present embodiment similarly to FIG. 4. The output mirror 400 of the present embodiment is different from the output mirror 400 of the first embodiment in a moth eye structure in which the reflection suppressing structure 402 is provided on the other main surface 412 of the sapphire substrate 410.

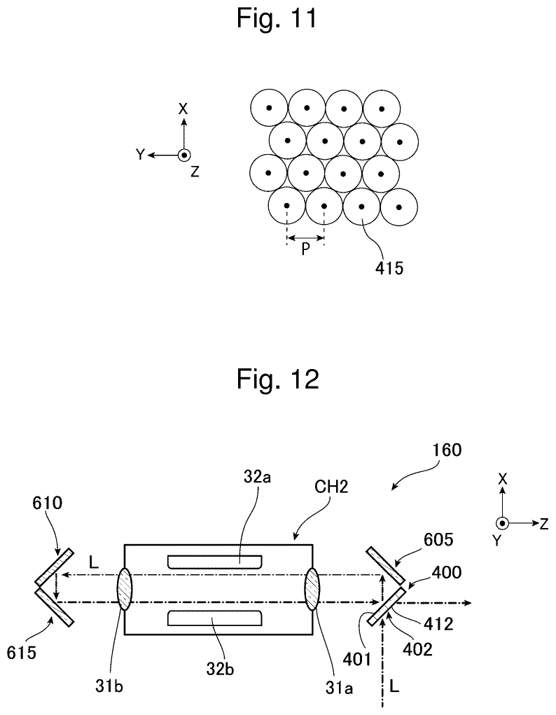

FIG. 11 is a schematic diagram illustrating the moth eye structure. The moth eye structure includes a large number of protrusion-shaped structures 415 aligned at regular intervals, and a pitch size P of the structures 415 is smaller than a wavelength of an ultraviolet laser beam L. In other words, when the wavelength of the ultraviolet laser beam L generated by the ultraviolet laser apparatus 100 of the present embodiment is 193 nm, the pitch size P of the structures 415 is smaller than 193 nm.

The protrusion-shaped structures 415 are, for example, conical. However, the shape of the structures 415 is not limited to a cone and may be a spindle shape or a pyramid. In addition, it is preferable that the height of the structures 415 be larger than the pitch size P. Note that methods of forming the moth eye structure on the other main surface 412 of the sapphire substrate 410 can include, for example, dry etching.

### 4.2 Effect and Advantage

In the present embodiment, the output mirror 400 can realize the incident surface and the exit surface of the ultraviolet laser beam L without using the dielectric multilayer film. Therefore, the output mirror 400 of the present embodiment can be more durable for the high-output ultraviolet laser beam L, and the ultraviolet laser apparatus 100 including the output mirror 400 of the present embodiment can be more durable.

Note that the application of the reflection suppressing function achieved by the moth eye structure is not limited to the output mirror 400, and the reflection suppressing function may be used for other optical elements of the ultraviolet laser apparatus 100.

### 5. Description of Ultraviolet Laser Apparatus of Third Embodiment

Next, an ultraviolet laser apparatus 100 of a third embodiment will be described. Note that the same components as those described above will be denoted by the same reference signs, and repeated description thereof will be omitted unless specifically explained.

### 5.1 Configuration

FIG. 12 is a schematic diagram illustrating a schematic configuration example of a part of an amplifier 160 included in the ultraviolet laser apparatus 100 of the present embodiment. In the ultraviolet laser apparatus 100 of the present embodiment, the amplifier 160 includes a ring-type resonator. Note that the ultraviolet laser apparatus 100 may be, for example, any of an ArF excimer laser apparatus and a KrF excimer laser apparatus.

In the present embodiment, the amplifier 160 amplifies energy of an ultraviolet laser beam L. The amplifier 160 of the present embodiment is different from the amplifier 160 of the first embodiment in that the amplifier 160 of the present embodiment includes high reflective mirrors 605, 610, and 615.

In the present embodiment, the output mirror 400 is disposed at a position that is inclined by 45° with respect to the optical axis of the ultraviolet laser beam L exiting a chamber device CH2 and faces the window 31a of the chamber device CH2. The high reflective mirror 605 is disposed to be aligned with the output mirror 400 at a position facing the window 31a of the chamber device CH2 to form an angle of 90° with the output mirror 400. The high reflective mirror 610 is disposed at a position facing the window 31b with an inclination of 45° with respect to the ultraviolet laser beam L exiting the chamber device CH2 on the side opposite to the output mirror 400 with the chamber device CH2 sandwiched therebetween. The high reflective mirror 615 is disposed to be aligned with the high reflective mirror 610 at a position facing the window 31b of the chamber device CH2 to form an angle of 90° with the high reflective mirror 610.

Note that the configuration of the output mirror 400 is similar to that of the output mirror 400 of the ultraviolet laser apparatus 100 in the first embodiment, the modifications of the first embodiment, or the second embodiment.

### 5.2 Operation

The ultraviolet laser beam L from a laser oscillator 130 is incident from a main surface 412 on which a reflection suppressing structure 402 is provided, and is transmitted through the output mirror 400. The ultraviolet laser beam L transmitted through the output mirror 400 is reflected by the high reflective mirror 605 to pass between the electrode 32a and the electrode 32b from the window 31a. The ultraviolet laser beam L that has passed through the inside of the chamber device CH2 and has been amplified exits the window 31b, is reflected by the high reflective mirror 610 and the high reflective mirror 615, passes again between the electrode 32a and the electrode 32b of the chamber device CH2 from the window 31b to be amplified, and then exits the window 31a. Thereafter, the ultraviolet laser beam L is incident on the output mirror 400. Since the output mirror 400 is disposed to be inclined by 45° with respect to a traveling direction of the ultraviolet laser beam L exiting the chamber device CH2, the ultraviolet laser beam L is incident from the side of the partial reflective surface 401 of the output mirror 400 at an incident angle of 45°. A part of the ultraviolet laser beam L that has been incident on the output mirror 400 is reflected by the partial reflective surface 401 of the output mirror 400, is incident on and reflected by the high reflective mirror 605, is incident on the chamber device CH2 again, and is then amplified. The other part of the ultraviolet laser beam L that has been incident on the output mirror 400 is transmitted through the output mirror 400 and exits the amplifier 160.

### 5.3 Effect and Advantage

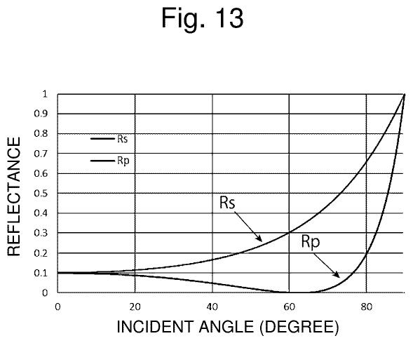

FIG. 13 is a graph illustrating a relationship between a Fresnel reflectance and an incident angle at a wavelength of 193 nm for each polarization direction. As illustrated in FIG. 13, when the incident angle is 45°, the Fresnel reflectance is 18.8% with respect to S-polarized light, and the Fresnel reflectance is 3.6% with respect to P-polarized light. Therefore, the output mirror 400 is an output mirror having a reflectance of approximately 19% with respect to the S-polarized light. Similarly to the other embodiments, the output mirror 400 in the present embodiment is not provided with the partial reflective film including the dielectric multilayer film, and the ultraviolet laser apparatus 100 with a high output and high durability can thus be realized.

Note that the configuration of the amplifier 160 in the embodiments may be applied to a laser oscillator that is a first stage of an ultraviolet laser apparatus based on a multistage amplification system, or may be applied to a plurality of amplifiers. The configuration of the output mirror 400 may be applied to an output mirror of a single laser oscillator.

The description above is intended to be illustrative and the present disclosure is not limited thereto. Therefore, it would be obvious to those skilled in the art that various modifications to the embodiments of the present disclosure would be possible without departing from the spirit and the scope of the appended claims. Further, it would be also obvious to those skilled in the art that embodiments of the present disclosure would be appropriately combined. The terms used throughout the present specification and the appended claims should be interpreted as non-limiting terms unless clearly described. For example, terms such as “comprise”, “include”, “have”, and “contain” should not be interpreted to be exclusive of other structural elements. Further, indefinite articles “a/an” should be interpreted to mean “at least one” or “one or more.” Further, “at least one of A, B, and C” should be interpreted to mean any of A, B, C, A+B, A+C, B+C, and A+B+C as well as to include combinations of the any thereof and any other than A, B, and C.

What is claimed is:

1. An output mirror for an ultraviolet laser beam, the output mirror comprising:
a plate-shaped sapphire substrate,
at least a part of one main surface of the sapphire substrate being a partial reflective surface that is exposed, reflects a part of the ultraviolet laser beam, and transmits another part of the ultraviolet laser beam,
the other main surface of the sapphire substrate being provided with a reflection suppressing structure configured to suppress reflection of the ultraviolet laser beam.

2. The output mirror according to claim 1, wherein the reflection suppressing structure includes a moth eye structure provided on the other main surface of the sapphire substrate.

3. The output mirror according to claim 1, wherein the reflection suppressing structure includes a structure including a dielectric multilayer film.

4. The output mirror according to claim 1, wherein the ultraviolet laser beam is an ArF laser beam or a KrF laser beam.

5. The output mirror according to claim 1, wherein a c axis of a sapphire crystal, which is a material of the sapphire substrate, is parallel to the one main surface.

6. The output mirror according to claim 1, wherein a material of the sapphire substrate is a sapphire crystal, a c axis of the sapphire crystal being perpendicular or parallel to a polarization direction of the ultraviolet laser beam.

7. The output mirror according to claim 1, wherein a material of the sapphire substrate is a sapphire crystal, a c axis of the sapphire crystal being perpendicular to the one main surface.

8. The output mirror according to claim 1, wherein a material of the sapphire substrate is a sapphire crystal, a c axis of the sapphire crystal being parallel to a traveling direction of the ultraviolet laser beam.

9. The output mirror according to claim 1, wherein a material of the sapphire substrate is a sapphire crystal, a c axis of the sapphire crystal being perpendicular to an inclination axis of a window and a traveling direction of the ultraviolet laser beam, the ultraviolet laser beam exiting from the window, the window being provided in a chamber device and being inclined around the inclination axis at a center with respect to an exit direction of the ultraviolet laser beam.

10. The output mirror according to claim 1, wherein the sapphire substrate has a thickness of equal to or greater than 1 mm and equal to or less than 7 mm.

11. The output mirror according to claim 1, wherein the sapphire substrate has a thickness of equal to or greater than 1 mm and equal to or less than 5 mm.

12. An ultraviolet laser apparatus comprising:
an amplifier configured to amplify an ultraviolet laser beam,
the amplifier including an output mirror for the ultraviolet laser beam,
the output mirror including a plate-shaped sapphire substrate,
at least a part of one main surface of the output mirror being a partial reflective surface from which the sapphire substrate is exposed, the partial reflective surface reflecting a part of the ultraviolet laser beam and transmitting another part of the ultraviolet laser beam,
the other main surface of the output mirror being provided with a reflection suppressing structure configured to suppress reflection of the ultraviolet laser beam.

13. The ultraviolet laser apparatus according to claim 12, wherein a material of the sapphire substrate is a sapphire crystal and the output mirror is disposed such that a c axis of the sapphire crystal is perpendicular or parallel to a polarization direction of the ultraviolet laser beam.

14. The ultraviolet laser apparatus according to claim 12, wherein a material of the sapphire substrate is a sapphire crystal and the output mirror is disposed such that a c axis of the sapphire crystal is parallel to a traveling direction of the ultraviolet laser beam.

15. The ultraviolet laser apparatus according to claim 12, wherein a material of the sapphire substrate is a sapphire crystal and the output mirror is disposed such that a c axis of the sapphire crystal is perpendicular to an inclination axis of a window and a traveling direction of the ultraviolet laser beam, the ultraviolet laser beam exiting from the window, the window being provided in a chamber device and being inclined around the inclination axis at a center with respect to an exit direction of the ultraviolet laser beam.

16. The ultraviolet laser apparatus according to claim 12, wherein the amplifier is a ring-type resonator.

17. The ultraviolet laser apparatus according to claim 16, wherein the output mirror of the amplifier is disposed to be inclined by 45° with respect to a traveling direction of the ultraviolet laser beam exiting a chamber device included in the amplifier, and the ultraviolet laser beam is incident on the other main surface of the output mirror.

18. An electronic device manufacturing method comprising:
generating an ultraviolet laser beam with an ultraviolet laser apparatus including an output mirror for the ultraviolet laser beam,
the output mirror including a plate-shaped sapphire substrate,
at least a part of one main surface of the output mirror being a partial reflective surface from which the sapphire substrate is exposed, the partial reflective surface reflecting a part of the ultraviolet laser beam and transmitting another part of the ultraviolet laser beam,
the other main surface of the output mirror being provided with a reflection suppressing structure configured to suppress reflection of the ultraviolet laser beam;
outputting the ultraviolet laser beam to an exposure apparatus; and
exposing a photosensitive substrate to the ultraviolet laser beam within the exposure apparatus to manufacture an electronic device.
